(19) United States
(12) Patent Application Publication
(10) Pub. No.: US 2015/0091646 A1
(43) Pub. Date: Apr. 2, 2015

(54) CURRENT MODE CLASS AB LOW-NOISE AMPLIFIER AND METHOD OF ACTIVE CABLE TERMINATION

(71) Applicant: Supertex, Inc., Sunnyvale, CA (US)

(72) Inventor: Lazar Shifrin, San Jose, CA (US)

(73) Assignee: Supertex, Inc., Sunnyvale, CA (US)

(21) Appl. No.: 14/042,361

(22) Filed: Sep. 30, 2013

(51) Int. Cl. H03F 3/21; H03F 3/26; H03F 3/45; H03F 3/193

(52) U.S. Cl. CPC H03F 3/21; H03F 3/193; H03F 3/265; H03F 3/45071; H03F 2203/45112; H03F 2203/45262
USPC 330/255

(57) ABSTRACT

This invention relates to medical ultrasonic imaging systems and, in particular, phased array imaging systems operating in different scan formats and imaging modalities. More specifically, the invention relates to the front-end processing of ultrasonic echoes.

### TECHNICAL FIELD

This invention relates to medical ultrasonic imaging systems and, in particular, phased array imaging systems operating in different scan formats and imaging modalities. More specifically, the invention relates to the front-end processing of ultrasonic echoes.

### BACKGROUND OF THE INVENTION

With the exception of CW Doppler, ultrasonic imaging systems use a pulse-echo method alternately functioning in two basic modes: transmit and receive. In the transmit mode, one or more transducer elements are excited by electrical pulses emitted by a transmitter, TX. During propagation within the tissue, acoustic waves are echoed back towards the transducer. Then, in the receive mode, ultrasound echoes are converted by the same transducer element into electrical signals. These analog signals are directed to a front-end, which typically comprises a low-noise amplifier (LNA) and time-gain compensation (TGC) circuitry followed by an anti-aliasing filter (AAF) and an analog-to-digital converter (ADC).

Processing signals from the transducer, the LNA must not compromise their frequency or signal-to-noise characteristics. In particular, since losses from tissue attenuation and reflection losses at tissue interfaces can produce 80-100 dB variations in echo amplitude, a 100-dB LNA dynamic range is considered the minimum requirement for diagnostic applications.

There are two factors limiting dynamic range of an LNA: noise and distortions. The first is the noise floor, e₀, which limits the smallest input that can be detected. In other words, the noise floor determines the maximum depth of penetration at a given operating frequency and amplitude of the transmitted pulses. The second limiting factor is the allowed level of total harmonic distortion (THD) at the LNA output, which specifies the largest input signal that a receiver can handle.

Considering LNA noise, it should be noted that ultrasonic transducers are connected to the LNA through a coaxial cable. Thus, to optimize power transfer and to avoid signal reflections, an LNA should also provide specific input impedance, such as 50 Ohm, to terminate the transmission line, i.e., transducer cable. A good input impedance match is even more critical wherein the transducer preceding the LNA is piezoelectric because such transducers are sensitive to the constancy of the terminating impedance.

There are three prior-art techniques of the transducer cable termination that have been widely employed in medical ultrasound imaging.

In the first topology shown in FIG. 1, the input signal produced by a transducer 101 is applied to a high input impedance LNA 102 via a transmit/receive switch 103 whereas a conventional resistor, R_{T}, 104 terminates the transducer cable 105. The shortcoming of this solution is that the termination resistor 104 contributes thermal noise. Typically, employing conventional or passive termination of the transducer cable, the SNR (signal-to-noise ratio) is decreased by a factor of 3 dB.

The second technique of cable impedance matching is often referred as 1/gₘ termination. It employs the source (emitter) of a conventional common-gate (-base) LNA as the termination point. Implementing this simple technique, the theoretical minimum of achievable noise figures tends to be around 3 dB. Consequently, the 1/gₘ termination method was widely used in the early developed ultrasound imaging systems (by the way of example, see FIG. 2). However, operating in a class A voltage mode, power dissipation of a single common-gate ultrasound LNA is quite substantial. For instance, the CLC5509 Preamplifier of FIG. 2 runs off ±5V power supplies consuming 11 mA or 110 mW. In contrast, a fully-integrated octal-channel front-end IC MD3872 consumes 95 mW per channel.

The third technique of active cable termination is shown in FIG. 3. In such embodiments, termination is provided by equivalent impedance at the summing node of an operational amplifier (Op Amp), 302, whereas a feedback resistor, R_{FB}, 304, is inserted between the Op Amp's non-inverting output and inverting input. Because of this feedback, the impedance looking into the inverting input is reduced by a factor 1+G, where G is the open-loop gain. Having transducer cable, 305, directly connected to the Op Amp's inverted input, the above configuration is used in numerous ultrasound front-end ICs.

An extensive study of active termination by the input impedance of an inverting feedback amplifier can be found in an article by M. Koen, “Ultrasound Processor Supplementary Material”, Burr-Brown Products Application Bulletin from Texas Instruments, AB-170, 2000.

FIG. 4 depicts known in the art topology of an ultrasound front-end that implements active termination technique. This front-end comprises a transducer 401, a low-noise amplifier (LNA) 402, encompassing a differential input/output Op Amp, a programmable feedback resistor 404 and a resistor network 406, which sets the Op Amp's open loop gain, G.

In the receive mode operation, the T/R switch (not shown) connects the transducer cable to the inverting input of the LNA 402. Consequently, the cable 405 is terminated by virtual impedance, R_{T}, seen at the inverting input node. As well known,

R_{T}=R_{FB}/1+G (1)

Alternatively, since R_{T} should be equal to the transducer cable impedance, ρ,

G=R_{FB}/ρ−1 (2)

In practice, in order to support 1 V_{P-P} linear input range, the industry's leading LNAs are arranged to provide a gain of 12 dB (4×). Thus, if a phased-array transducer is connected with the ultrasound scanner by a 50-Ohm multi-conductor cable, R_{FB}=ρ·(1+G)=250 Ohm.

Removal of a physical termination resistor results in improving noise figure of the LNA. However, active termination technique known in the art suffers from limited bandwidth of the feedback loop setting the Op Amp gain because of the following reason:

Since active termination of a cable having characteristic impedance, ρ, is provided at the summing node of an Op Amp, its open-loop gain, G, and feedback resistor, R_{FB}, are set to comply with the equality

$$\frac{{R}_{FB}}{1 + G} = ρ .$$

However, for the high-frequency transducers, there is a chance that the uppermost frequency harmonic of an input signal is above the −3 dB bandwidth of the open-loop gain. In such a case, said loop gain becomes bandlimited.

Assume for simplicity that the open-loop gain, G, varies with frequency like a first-order low-pass filter having a time constant T. Accordingly, its Laplace transform, G(s), can be written as:

$$G ( s ) = \frac{{G}_{0}}{1 + sT} \qquad ( 3 )$$

where s and G₀ are the Laplace operator and the open-loop gain at DC, respectively. As a result, the impedance at the inverting Op Amp's node becomes a complex variable, Z_{IN}(s), defined by the following equation:

$${Z}_{IN} ( s ) = \frac{{R}_{FB}}{1 + G ( s )} \qquad ( 4 )$$

Insertion Eq. (3) in Eq. (4) yields:

$${Z}_{IN} ( s ) = \frac{{R}_{FB}}{1 + {G}_{0}} \cdot \frac{1 + sT}{1 + \frac{sT}{1 + {G}_{0}}} \qquad ( 5 )$$

Eq. (5) shows that the equivalent impedance at the summing node increases with frequency from the nominal value of ρ at DC to R_{FB} at high frequencies FIG. 5 depicts an equivalent circuit that corresponds to the Z_{IN} and, therefore, seen by the transducer cable. Said circuit comprises the following components:

R0_{IN}=ρ·(1+G₀)

R1_{IN}=ρ·(1+1/G₀)

L_{IN}=T·R1_{IN} (6)

Recalling circuit theory, if the load of a transmission line has any reactance, then the impedance along the line goes through a cycle of changing values that repeat themselves every half of a wavelength. This transformation of impedance is expressed by the Terman equation (Radio Engineers' Handbook, McGraw-Hill, 1943, page 186). Resolving Terman's impedance equation for a given length of the transducer cable, there will be multiple pairs of frequencies at which the imaginary part of the line-input impedance has the same value but opposing signs of reactance. FIG. 6 depicts SPICE simulations that illustrate the front-end behavior with conventional (i.e., passive) and active methods of cable termination. The obtained results refer to an 11 MHz ultrasound transducer connected via a 75-Ohm 6-ft cable. Active termination is provided by an LNA having the DC gain of 4 and the −3 dB bandwidth of 25 MHz.

During simulations, the transducer cable was sequentially switched between two LNAs that were arranged to employ two termination techniques, i.e., active and conventional. FIG. 6 clearly demonstrates that if active termination is limited in bandwidth, the transducer's frequency response exhibits multiple frequency peaks. Conversely, passive termination has no such artifacts.

Summarizing, ultrasonic LNAs are aimed to provide dynamic range in excess of 100 dB. Active termination by the input impedance of an inverting feedback amplifier allows minimizing the noise figure. However, frequency dependence of the LNA open-loop gain originates multiple frequency peaks at harmonics of the fundamental transducer frequency.

In medical ultrasound imaging, it is essential to achieve both low harmonic distortions and the minimum noise floor. Therefore, there is still a need for the development of a broadband front-end providing active termination.

### SUMMARY OF THE INVENTION

It is an object of the present invention to improve dynamic range and linearity of an ultrasonic LNA for medical imaging without degrading its noise performance.

Another object of the present invention is to provide programmable active termination of the transducer cable.

A further object of the present invention is to develop architecture of an ultrasonic LNA, which is suitable for integration using low-voltage process.

To accomplish these and other objects, the LNA consists of sequentially connected voltage-to-current (V-to-I) and current-to-voltage (I-to-V) converters.

In one embodiment, the implemented V-to-I converter (also known as transconductor) comprises two complementary and uniformly configured folded-cascode amplifiers connected in a push-pull relationship. Each folded-cascode amplifier consists of two (input and output) common-gate (CG) stages and operative to provide single-ended current output.

Further embodiments of the V-to-I converter employ two complementary and uniformly configured current mirrors.

One aspect of the present invention is a low-noise Class AB transconductor comprising two complementary folded-cascode amplifiers connected in a push-pull relationship.

Another aspect of the present invention is a method for controlling the transconductance parameter of said transconductor; the method comprising varying the bias currents of said input CG stages.

A further object of the present invention is a low-noise Class AB transconductor comprising two complementary current mirrors connected in a push-pull relationship.

A further object of the present invention is a low-noise Class AB transconductor comprising two complementary Wilson current mirrors connected in a push-pull relationship.

One more aspect of the present invention is providing active termination of the transducer cable by the input impedance of a Class AB transconductor; said impedance is adjustable.

A further aspect of the present invention is to propose method and means for minimizing the influence of the technological variations on the class AB transconductor performance. To achieve this objective, the invention discloses a method and apparatus, which detect a DC voltage bias of the transconductor output and appropriately adjust current biasing of the input CG stages.

### BRIEF DESCRIPTION OF THE DRAWINGS

The invention will be described with respect to particular embodiments therefrom referring to the following drawings:

FIG. 1 is a block diagram of a prior art ultrasound front-end with passive cable termination.

FIG. 2 is a schematic diagram of a prior art ultrasound LNA providing 1/gₘ termination.

FIG. 3 is a block diagram of a prior art ultrasound transducer receiver employing active termination.

FIG. 4 is a detailed block diagram of a prior art ultrasound LNA with active termination.

FIG. 5 is an equivalent prior art circuit model of bandlimited active cable termination.

FIG. 6 demonstrates simulation results of the front-end frequency response for two prior art termination techniques: conventional (passive) and bandlimited active.

FIG. 7 is a schematic diagram of a CMOS transconductor, which is primarily responsive for converting the negative portion of AC voltage signals into current flow.

FIG. 8 is a schematic diagram of the first embodiment for a Class AB ultrasound LNA.

FIG. 9 is a schematic diagram of the second embodiment for a Class AB ultrasound LNA.

FIG. 10 is a schematic diagram of the third embodiment for a Class AB ultrasound LNA.

FIG. 11 is a schematic diagram of the preferred embodiment for a Class AB ultrasound LNA.

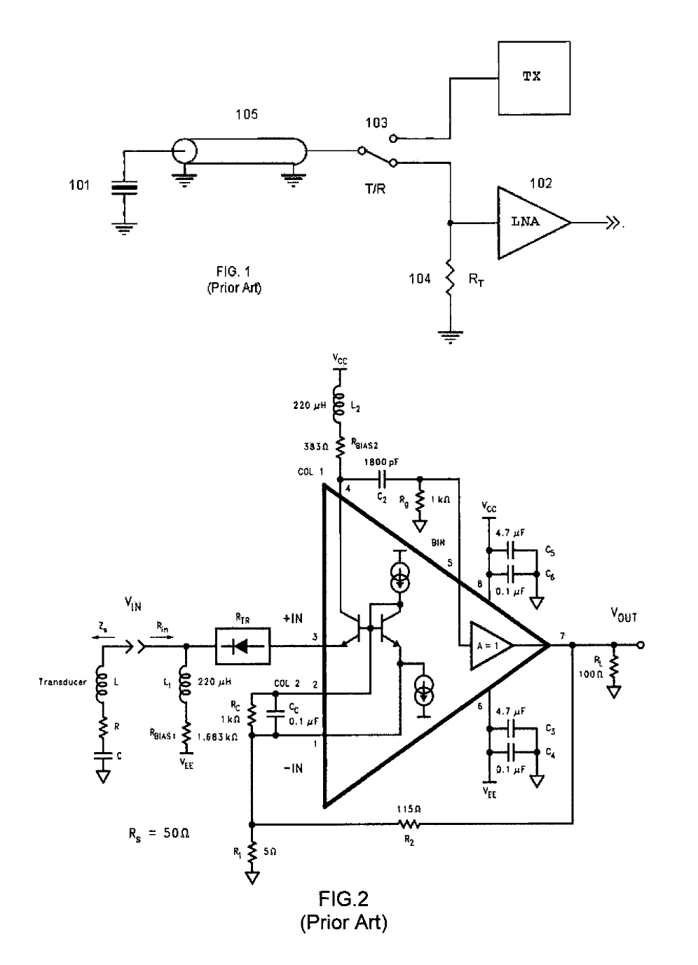

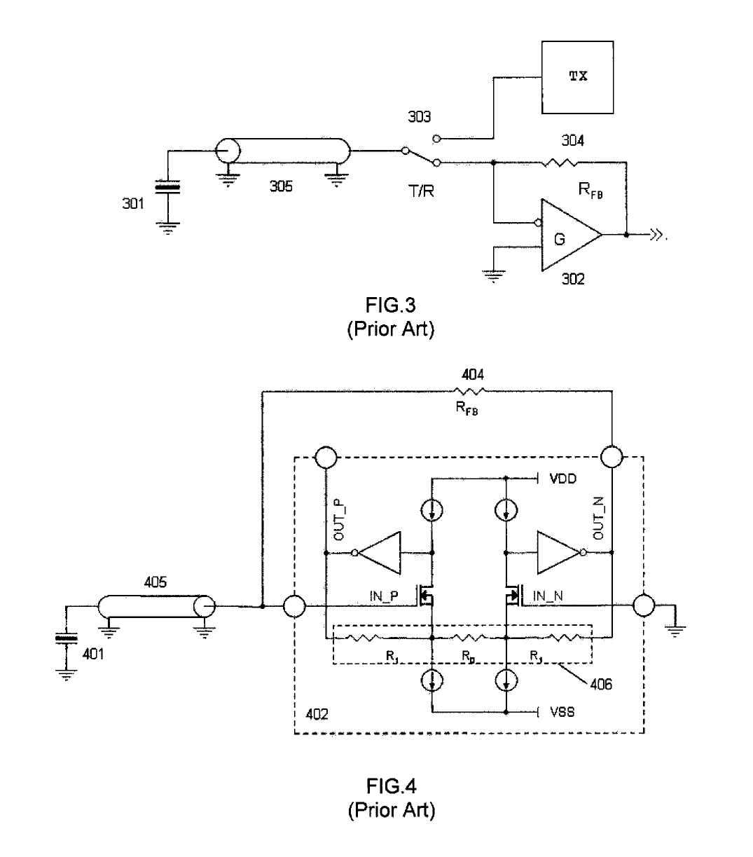

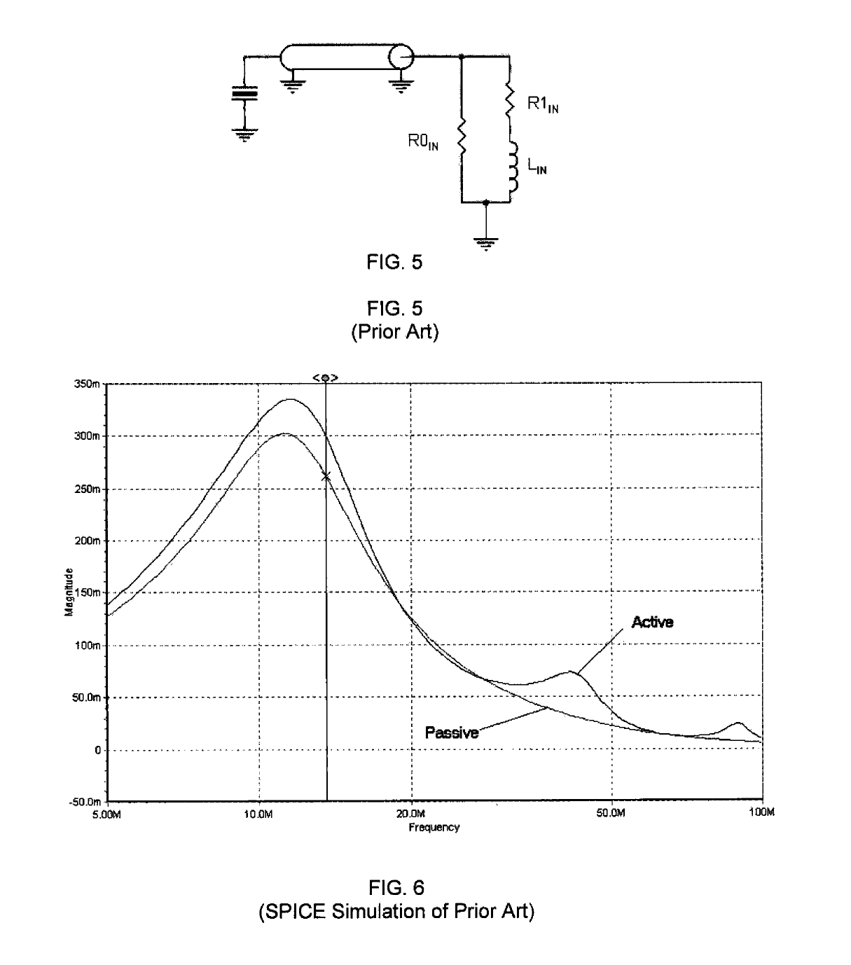

### DETAILED DESCRIPTION OF THE EMBODIMENTS

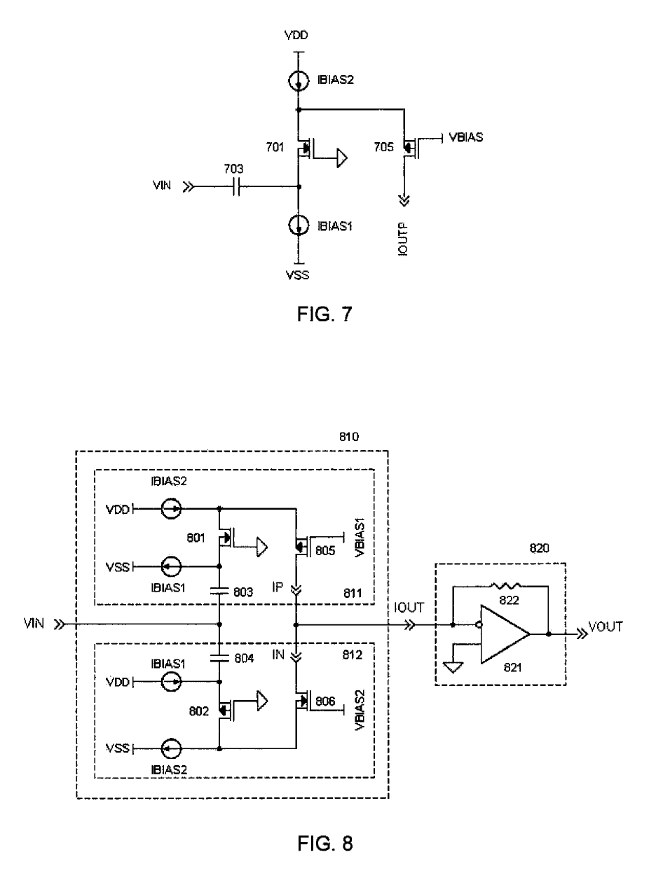

A description of the present invention is given with reference to FIGS. 7-11 wherein like parts are designated with like numerals throughout.

FIG. 7 depicts a unipolar Voltage-to-Current (V/I) conversion circuit 700. The circuit 700 is primarily responsive for converting the negative portion of AC voltage signals into current ones and comprises a folded cascode amplifier formed of a common-gate (CG) stage followed by another CG stage complementary to the preceding. Said conversion circuit encompasses:
voltage input node labeled VIN,
N-channel common-gate stage 701,
first bias current source labeled IBIAS1,
decoupling capacitor 703,
second bias current source labeled IBIAS2,
P-channel common-gate stage 705,
voltage bias source labeled VBIAS, and
output current node labeled IOUTP.

The first embodiment of a Class AB ultrasound LNA is shown in FIG. 8. This LNA consists of a transconductor operating in Class AB followed by a current-to-voltage (I/V) converter, which operates as a conventional Op Amp having a feedback resistor.

The transconductor 810 shown in FIG. 8 comprises two complementary and identically-configured unipolar V/I conversion circuits of FIG. 7, which provide the same or substantially same transconductance characteristics for positive and negative segments of the transducer signal, VIN. One unipolar V/I converter comprises a folded cascode CG-CG amplifier 811, and the other comprises a folded cascode amplifier 812, where the amplifier 812 is a complementary version of the amplifier 811. The output terminals of both V/I converters are connected in a push-pull relationship providing bipolar current flow, IOUT, to the I/V converter.

The theory of transconductor operation, i.e., V-to-I conversion is as follows:

In saturation mode, the drain current, I_{DN}, of an N-channel MOS transistor is expressed to first order as

I_{DN}=β·(V_{GSN}−V_{TN})² (7)

where V_{TN} and V_{GSN}=V_{GN}−V_{SN} are the threshold and gate-source voltages, respectively, β is the transconductance parameter. In its turn, the transconductance parameter is determined by the intrinsic (process) transconductance, k, and the channel aspect ratio, W/L, as:

$$β = \frac{kW}{L} \qquad ( 8 )$$

Referring to FIG. 6, V_{GN}=V_{GP}=0. Assume first that there is no input signal, VIN, applied to the source electrode via the capacitor, C. In these circumstances, only a DC bias current, IBIAS1, flows through the channel. Let I_{D0} denote a DC component of the drain current. Then, drain current of a NMOS transistor is I_{D0N}=IBIAS1, and substituting V_{GSN}=−V_{S}, we obtain

I_{D0N}=β·[(−V_{S0N}−V_{TN})]² (9)

where the term V_{S0N} denotes the source voltage at DC.
Solving the above equation with respect to V_{S0N} gives

$${V}_{S 0 N} - ( \sqrt{\frac{{I}_{D 0 N}}{β}} + {V}_{TN} ) \qquad ( 10 )$$

For a P-channel MOS transistor, a DC component of the drain current is given by

I_{D0P}=β·[(−V_{SGP}−V_{TP})]² (11)

Accordingly, for a PMOS transistor, the source voltage at DC becomes

$${V}_{S 0 P} = \sqrt{\frac{{I}_{D 0 P}}{β}} + {V}_{TP} \qquad ( 12 )$$

As well known, typical values of the process transconductance, k, for N- and P-cannel transistors are different (approximately by a factor 3). However, since the transconductance parameter is given by the Eq. 8, this difference can be compensated by appropriate adjustment of the transistors' aspect ratio, W/L. Consequently, the following analysis is based on the assumption of using complementary transistors having substantially equal transconductance parameter, β, and voltage thresholds, V_{T}.

In operation, an AC signal is simultaneously applied to both NMOS and PMOS transistors. Let ΔV denote the instantaneous value of an ultrasound echo. Thus, the resulting source voltages for N- and P-transistors can be represented by ΔV+V_{SON} and ΔV+V_{SOP}, respectively. Consequently, the drain currents, I_{DN} and I_{DP}, yield:

$${I}_{DN} = β \cdot {( Δ V - \sqrt{\frac{IBIAS 1}{β}} )}^{2} \\ {I}_{DP} = β \cdot {( Δ V + \sqrt{\frac{IBIAS 1}{β}} )}^{2} \qquad ( 13 )$$

Then, taking the difference between the drain currents produced by PMOS and NMOS transistors, the transconductor output can be expressed as

ΔI=I_{DP}−I_{DN}=4·ΔV·\sqrt{IBIAS1·β} (14)

Eq. 14 allows expressing input impedance of the proposed V/I converter, R_{IN}=ΔV/ΔI, as

$${R}_{IN} = \frac{1}{4 \sqrt{β \cdot IBIAS 1}} \qquad ( 15 )$$

As seen from Eq. 15, input impedance of the introduced class AB transconductor (V/I converter) is inversely proportion to the square root of the bias current, IBIAS1. Thus, the proposed technique essentially expands the range of impedance matching while optimizing both SNR and linearity features of the LNA. It will be also appreciated that the LNA input impedance is directly controlled by IBIAS1.

Important advantages of the embodiment shown in FIG. 8 can be summarized as follows:
1. There is a substantial improvement in the LNA dynamic range and linearity comparing with the prior art.
2. Transconductance (input impedance) of the circuit is easily controllable.
3. Entirely operating with currents rather than voltages, the proposed architecture is particularly suitable for low-voltage process technologies that support broadband applications.
4. Providing controllable input impedance, low noise, and wide dynamic range the proposed current mode Class AB LNA makes it easier to predict and obtain repeatable performance of the ultrasonic front-ends.

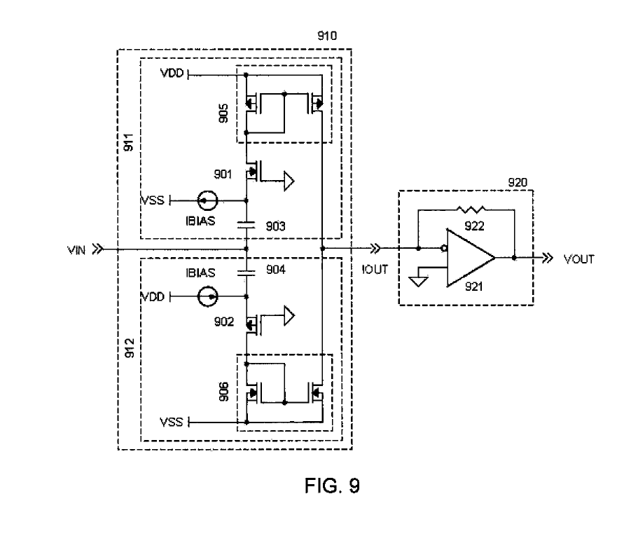

Another embodiment is depicted in FIG. 9. The difference between the LNAs of FIG. 8 and FIG. 9 is the use of current mirroring instead of current folding. This solution eliminates two precise current sources and allows simple scaling of the output current by properly choosing the mirror aspect ratio and, therefore, provides more flexibility to a designer.

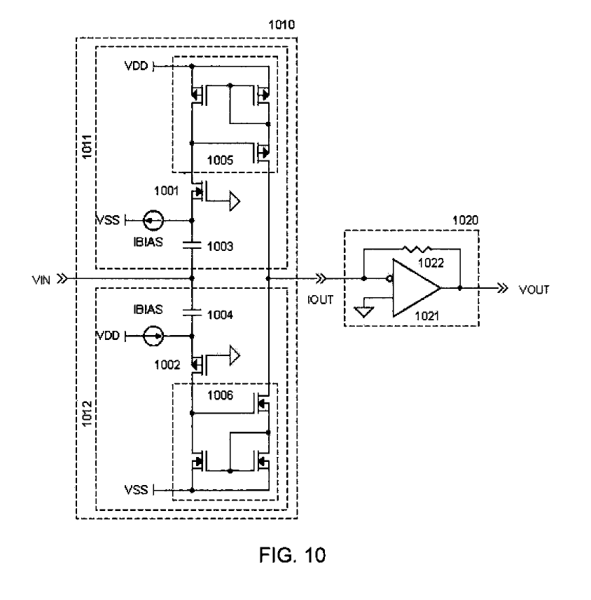

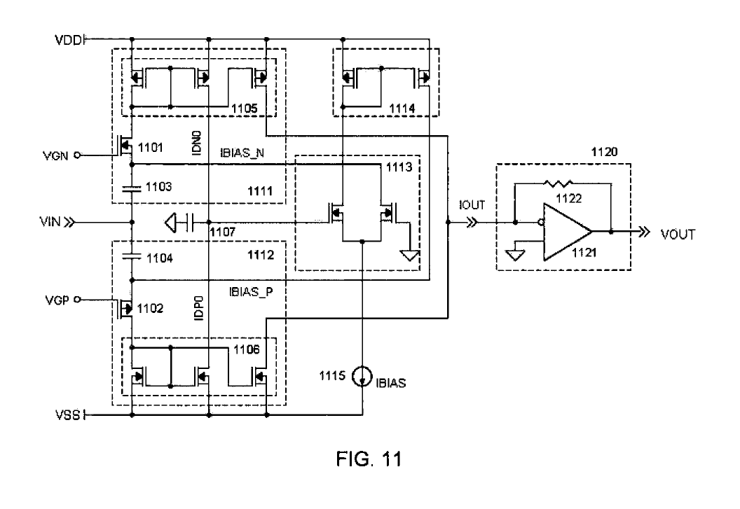

Yet another embodiment of a class AB ultrasound LNA is shown in FIG. 10. The difference between the LNAs of FIG. 9 and FIG. 10 is the use of the Wilson current mirrors for arranging the class AB transconductor. The purpose of this replacement is to increase output impedance of the transconductor and, thus, to improve accuracy of the entire signal processing chain.

As well known, process variations and changing environmental conditions may have an influence on the active circuitry, such as the V/I converters although the design thereof aims to minimize this influence. Accordingly, the following embodiment discloses a method and apparatus for minimizing said influence.

As mentioned above, the process transconductance parameters of PMOS, k_{P}, and NMOS, k_{N}, transistors are different, on average, by a factor of three. Following that, it has been assumed that the aspect ratio of the transistors 801 and 802 are related by the same factor. Accordingly, the transconductance parameter, β, of both P and NMOS transistors turned out to be substantially equal and the input impedance of the embodiments shown in FIGS. 8-10 will follow Eq. 15.

Practically, however, there is number of variations of the used technological process. For instance, the ratio of a pair of randomly selected process parameters, k_{N} and kₚ, may be different from its statistical average. Thus, one needs to compensate for difference between k_{N}/kₚ and 3 by appropriate adjusting the bias currents that flow through the CG amplifiers of FIGS. 8-10. Besides, process variations may include both die-to-die and within-die aspect ratio discrepancy.

FIG. 11 depicts a class AB ultrasound LNA that compensates said process transconductance variations using a feedback loop.

The LNA 1100 contains two complementary and identically-arranged unipolar V/I conversion circuits 1111 and 1112, IN converter 1120, and a feedback loop for regulation the bias currents of the CG amplifiers 1101 and 1102. Said loop includes two dual output current mirrors 1105 and 1106, an integrating capacitor 1107, a differential amplifier 1113, a simple current mirror 1114, and a current bias source 1115 labeled IBIAS. A theory of the loop operation is as follows:

Ideally, the CG amplifiers 1101 and 1102 are assumed to be of a substantially identical transconductance parameter. Accordingly, with no signals applied, the V/I conversion circuits 1111 and 1112 provide the same or substantially same current outputs. In such a case, the mirrored transconductor output currents, IDN0 and IDP0, are equal so that the voltage across integrating capacitor 1107 will remain constant. In other words, the loop exhibits a steady state, in which IDN0=IDP0=IBIAS/2.

Any misbalance in the transconductance parameter between transistors 1101 and 1102 produces a current flow charging/discharging the capacitor 1107. This produces a voltage feedback signal applied to the input of the differential amplifier 1113 that splits the bias current, IBIAS, into two unequal parts. One of these parts, IBIAS_N is directly produced by the amplifier 1113 and provides direct biasing of the CG amplifier 1101. The second bias current, IBIAS_P, is applied to the CG amplifier 1102 after its mirroring by the current mirror 1114. The above steps are repeated until a new equilibrium is set up.

The transconductor output node is created by connecting appropriate terminals of said dual output current mirrors 1105 and 1106.

While the invention has been described above by reference to various embodiments, it would be understood that many changes and modifications could be made without departing from the scope of the invention. For example, different Op Amps, sources of the bias current, or the fashion of their controlling may be used. It is therefore intended that the foregoing detailed description be understood as an illustration of the presently preferred embodiments of the invention, and not as a definition of the invention. It is only the following claims or added claims, including all equivalents, are intended to define the scope of this invention.

References to the present invention herein are not intended to limit the scope of any claim or claim term, but instead merely make reference to one or more features that may be covered by one or more of the claims. Materials, processes and numerical examples described above are exemplary only, and should not be deemed to limit the claims. It should be noted that, as used herein, the terms “over” and “on” both inclusively include “directly on” (no intermediate materials, elements or space disposed there between) and “indirectly on” (intermediate materials, elements or space disposed there between).

What is claimed is:

1. A low-noise amplifier (LNA) for receiving ultrasonic echo signals from a piezo-electric transducer via a coaxial cable having different characteristic impedance said LNA comprising: an input terminal, an output terminal, and a transconductor circuit sequentially connected to a current-to-voltage (I-to-V) converter, wherein the transconductance parameter of said transconductor circuit is operable to match the characteristic impedance of the cable.

2. The invention of claim 1, wherein said transconductor circuit comprises positive and a negative power rails referenced to ground, a pair of complementary and identically-configured folded-cascode amplifiers having same or substantially same transconductance characteristics, and wherein each of the folded-cascode amplifiers is operable to provide unipolar current output, said folded-cascode amplifiers connected in a push-pull relationship.

3. The invention of claim 2, wherein each of said folded cascade amplifiers comprises:
a bias voltage source;
a coupling capacitor;
first and second bias current sources;
an unipolar output;
first and second CMOS transistors of a complimentary conductivity, each of said transistors further comprising source, gate, and drain electrodes, said drain of the first transistor and said source of the second transistor coupled to a common connection point, said drain of the second transistor connected to the unipolar output.

4. The invention of claim 3, wherein:
the gate of said first transistor is grounded;
said first bias current source is arranged between the source electrode of the first transistor and a power rail having appropriate polarity as determined by the polarity of said transistor, and wherein the coupling capacitor is arranged between said source electrode and the input terminal;
said second bias current source arranged between the common connection point and the remaining power rail;
the gate of said second transistor coupled with the bias voltage source.

5. The invention of claim 3, wherein said first current bias source is adjustable.

6. The invention of claim 1, wherein said current-to-voltage converter contains an operational amplifier (Op Amp) and a feedback resistor; said operational amplifier comprising a positive input node, a negative input node, and an output node connected with the output terminal.

7. The invention of claim 5, wherein said positive input node is grounded, said negative input node coupled with the both unipolar outputs provided by the folded-cascode amplifiers.

8. A method for receiving ultrasonic echo signals from a piezo-electric transducer via coaxial cable with different characteristic impedance, the method comprising:
a) converting bipolar echo signals into RF current by means of a transconductor operating in class AB;
b) transforming said RF current into a voltage signal.

9. The method of claim 8, wherein the converting step comprises:
a) implementing a transconductor with finite transconductance parameter, gM; and
b) setting the transconductance parameter to be approximately equal to the reciprocal of said characteristic impedance.

10. The invention of claim 1, wherein the transconductance parameter is responsive to adjusting said first bias current source.

11. The invention of claim 1, wherein:
said transconductor circuit comprises positive and a negative power rails referenced to ground, a pair of complementary and identically-configured common-gate amplifiers having the same or substantially same transconductance characteristics, and a pair of complimentary current mirrors each having an input terminal, a common terminal and an output terminal, and wherein:
the common terminals of said current mirrors being coupled to appropriate power rails, the input terminals of said current mirrors being coupled with drain electrode of appropriate common-gate amplifier, the output terminals of said current mirrors are connected in a push-pull relationship providing an output current signal to said IN converter.

12. The invention of claim 11, wherein:
each of said common-gate amplifiers comprises a coupling capacitor, a bias current source, an output terminal, and wherein:
the gate of said common-gate amplifiers is grounded, said bias current sources are arranged between the source electrode of the common-gate amplifier and a power rail having appropriate polarity as determined by the polarity of said amplifier, and wherein the coupling capacitor is arranged between said source electrode and the input terminal.

13. The invention of claim 9, wherein the step of setting the transconductance parameter is provided by a feedback loop.

14. The invention of claim 11, wherein:
said pair of complimentary current mirrors is arranged as a pair of dual-output mirrors having an input terminal, a common terminal, and two output terminals, wherein each of said output terminals is connected to its counterpart in a push-pull relationship for providing two single-ended bipolar signals, and wherein said bipolar signals are used for closing said feedback loop and driving the IN converter.

15. The invention of claim 13, wherein said step of transconductance setting comprises detecting the difference between drain currents of said common-gate amplifiers, integrating this difference, comparing the produced voltage signal with zero, amplifying the obtained error signal by means of a differential amplifier having a tail current source, and using the differential amplifier current outputs for biasing the common-gate amplifiers.

16. The invention of claim 15, wherein the transconductor circuit of claim 11 additionally comprises an integrating capacitor, a simple current mirror, and a differential amplifier operable to split its tail current, IBIAS, between said common-gate amplifiers.

17. The invention of claim 16, wherein:
the differential amplifier has two inputs, one of which is grounded, and two (inverting and non-inverting) outputs;
the integrating capacitor is coupled between ground and the second amplifier's input;
the inverting output of said differential amplifier is connected to the input of the simple current mirror; and
the currents generated at the non-inverting output of the differential amplifier and by said simple mirror are used for biasing said complimentary common-gate amplifiers.
